(19) United States
(12) Patent Application Publication
(10) Pub. No.: US 2008/0266794 A1
(43) Pub. Date: Oct. 30, 2008

(54) Processor control of cooling fluid

(76) Inventor: Christopher Gregory Malone, Loomis, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/796,860

(22) Filed: Apr. 30, 2007

(51) Int. Cl. H05K 7/20

(52) U.S. Cl. 361/695; 361/689; 361/699

(57) ABSTRACT

A processor of an apparatus in one example is configured to control at least one characteristic of a cooling fluid supplied to an electronic component based on a temperature rise of the cooling fluid between an inlet and an outlet of the electronic component.

### BACKGROUND

The air temperature rise between an inlet and outlet of an electrical component, such as a server or computer, has generally been limited to approximately 10C to assure minimal impacts of exhaust air on surrounding cables and equipment. In recent years, as server power has increased dramatically and systems have become more compact, this has become more difficult. For example, in the latest generation of blade servers, a temperature rise of 35C is feasible, which may generate exhaust air temperatures of 70C or 158F. However, extremely high exhaust air temperatures may be difficult to manage in the typical data center, where many servers may be located in close proximity. If intake air for the servers is not isolated from their exhaust air, mixing of the intake air with hot exhaust air may cause overheating and shutdowns.

### SUMMARY

The invention in one implementation encompasses an apparatus. The apparatus comprises a processor that is configured to control at least one characteristic of a cooling fluid supplied to an electronic component based on a temperature rise of the cooling fluid between an inlet and an outlet of the electronic component.

Another implementation of the invention encompasses a method. A desired temperature rise is determined for at least one electronic component in a rack of a data center to reduce energy used to supply cooling fluid to the at least one electronic component. At least one characteristic of the cooling fluid supplied to the at least one electronic component is controlled to maintain the desired temperature rise for the at least one electronic component.

A further implementation of the invention encompasses a computer readable storage medium. At least one computer program is embedded on the computer readable storage medium. The computer program comprises a set of instructions for: determining a desired temperature rise for at least one electronic component in a rack of a data center to reduce energy used to supply cooling fluid to the at least one electronic component; and controlling at least one characteristic of the cooling fluid supplied to the at least one electronic component to maintain the desired temperature rise for the at least one electronic component.

### DESCRIPTION OF THE DRAWINGS

Features of example implementations of the invention will become apparent from the description, the claims, and the accompanying drawings in which:

FIG. 1 is a representation of one implementation of an apparatus that comprises a data center with at least one rack and at least one computer room air conditioner.

FIG. 2 is a representation of one implementation of a logic flow for cooling of the rack of the apparatus of FIG. 1.

### DETAILED DESCRIPTION

Referring to the BACKGROUND section above, energy consumed by operating fans or pumps is an increasing cost for operation of a data center that may consume more than 10% of the total data system energy. Air conditioning energy consumption represents a significant portion of the total data center operation cost, which may be as high as double the energy used for operating the servers. Minimizing costs of operating the air conditioning equipment and the fans or pumps leaves more energy available for useful computational work by the servers. One advantage of a high temperature rise is that airflow through the servers can be reduced, which reduces energy usage to power the fans and reduces the load on the air conditioning equipment.

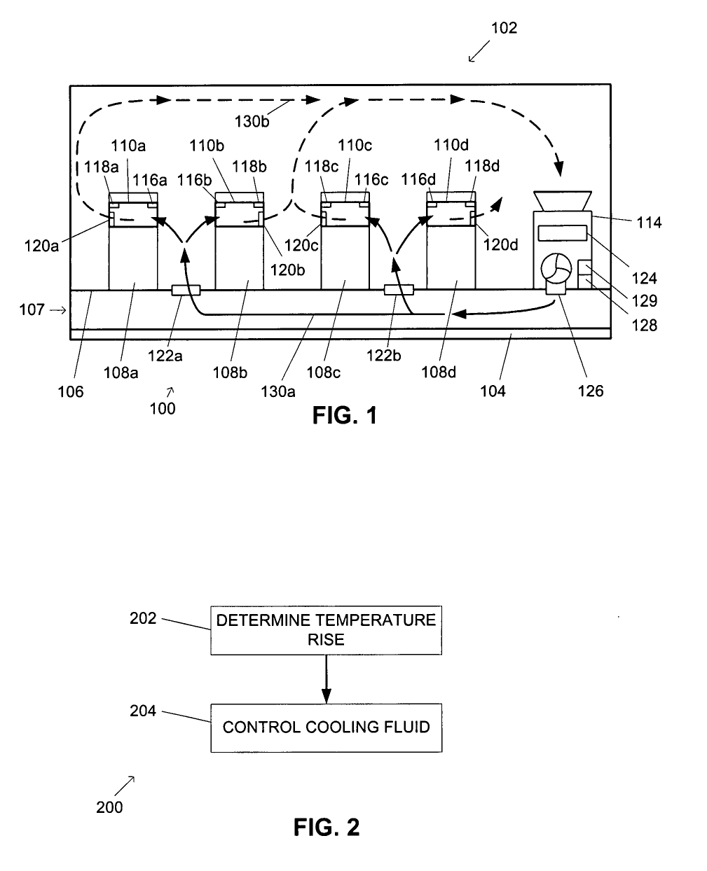

Turning to FIG. 1, an apparatus 100 in one example comprises a data center 102. The data center 102 in one example comprises a base floor 104 and a raised floor 106 which provide a plenum 107 therebetween for cooling fluid, as described herein. The data center 102 comprises at least one rack or cabinet 108 with at least one electronic component 110 and at least one fluid cooler 114.

In the implementation of FIG. 1, the data center 102 comprises racks 108a, 108b, 108c, and 108d. Racks 108a, 108b, 108c, and 108d comprise electronic components 110a, 110b, 110c, and 110d, such as a rack-mount server, storage unit, or blade enclosure. Additional instances of the electronic component 110 may be placed within the racks 108. Operation of the electronic components 110 generates heat, which must be dissipated to prevent overheating. Dissipation of the heat is increased by pumping or flowing a cooling fluid through and/or around the electronic components 110, as will be appreciated by those skilled in the art. Examples of cooling fluid are air, liquid coolants such as water, and refrigeration coolants such as R-12 and R-134a.

The electronic components 110 comprise a plurality of temperature sensors, for example, inlet temperature sensors 116 and outlet temperature sensors 118. The temperature sensors 116 and 118 in one example may be coupled with the racks 108 (e.g., to a frame or door of the rack) and/or the electronic components 110. In another example, the temperature sensors 116 and 118 may be integral with the racks 108 and/or the electronic components 110. The temperature sensors 116 and 118 serve to provide a temperature of the cooling fluid as it passes through and/or around the racks 108 and electronic components 110. In one example, the temperature sensors 116 and 118 may be coupled with processors or memory units of the electronic components 110.

The racks 108 in the implementation of FIG. 1 comprise a plurality of fans 120 (e.g., variable output fans) for delivery of the cooling fluid. For example, the electronic components 110 are air-cooled by the fans 120. The raised floor 106 comprises at least one vent 122 for delivery of the air. The fluid cooler 114 in one example comprises a computer room air conditioner (CRAC), cooling tower, water chiller, or refrigeration system. The fluid cooler 114 comprises a heat exchanger 124 that removes heat from the cooling fluid. In the implementation of FIG. 1, the fluid cooler 114 comprises a fan 126 (e.g., variable output fan) that directs the cooling fluid into the plenum 107.

The fluid cooler 114 in one example comprises a processor or fluid cooler controller 128. The processor 128 is configured to control at least one characteristic of the cooling fluid based on a temperature rise of the cooling fluid. In one example, the processor 128 is communicatively coupled with the inlet temperature sensors 116 and the outlet temperature sensors 118. In a further example, the processor 128 is communicatively coupled with the fans 120, the vents 122, and the fans 126. In an alternative implementation, the processor 128 may be located within a data center management server or an electronic component 110 of the racks 108, as will be appreciated by those skilled in the art. The processor 128 in one example is coupled with an instance of a recordable data storage medium 129.

An illustrative description of operation of the apparatus 100 is presented, for explanatory purposes. In the implementation of FIG. 1, the cooling fluid is air. The fluid cooler 114 supplies cold air for cooling the racks 108 and electronic components 110. The fans 120 and 126 and vents 122 create a fluid delivery path 130 between the electronic components 110 and the fluid cooler 114. For example, the fan 126 pushes cold air 130a into the plenum 107. The cold air 130a is passed through the vents 122 to the electronic components 110. The electronic components 110 receive the cold air 130a through an inlet with the inlet temperature sensors 116. The electronic components 110 transfer heat to the cold air 130a and exhaust it as hot air 130b through an outlet with the outlet temperature sensors 118. The fluid cooler 114 draws in and removes heat from the hot air 130b through employment of the heat exchanger 124. The heat exchanger 124 in one example transfers the heat outside of the data center 102. The heat exchanger 124 provides cold air, which is circulated through the fluid delivery path 130, as will be appreciated by those skilled in the art.

The processor 128 monitors the inlet temperature sensors 116 and the outlet temperature sensors 118. The processor 128 in one example determines a temperature rise of the cooling fluid between the inlet and outlet. The processor 128 is configured to control at least one characteristic of the cooling fluid based on the temperature rise. Examples of the characteristics that may be controlled by the processor 128 are: the velocity of the cooling fluid, the volume of the cooling fluid, the fluid delivery path 130, and the temperature of the cooling fluid. For example, the processor 128 may adjust the fans 120 and 126 (e.g., reduce or increase rotational speed), the vents 122 (e.g., closed, open, partially open), and temperature of the cooling fluid (e.g., 30C, 25C, etc.).

The processor 128 in one example maintains a desired temperature rise or outlet temperature of the cooling fluid. In one example, the processor 128 determines the desired temperature rise to reduce energy used to supply the cooling fluid and maintain the electronic components 110 within a desired operating temperature range. The desired temperature rise in one example is based on at least one characteristic of an environment of the electronic components. Examples of characteristics of the environment comprise the cooling capacity of the fluid cooler 114, a cooling efficiency of the fluid cooler 114, and the fluid delivery path 130.

In a first example, a well-defined fluid delivery path is formed with ducts, enclosed pathways, and fans to prevent the hot air 130b from mixing with the cold air 130a. The well-defined fluid delivery path allows a larger temperature rise and accordingly a higher outlet temperature with lower fan speeds, which reduces energy used for providing the cooling fluid. The processor 128 would operate the fans 120 and 126 at a lower speed or perhaps allow certain fans to be turned off or removed. The energy saved may enable additional electronic components 110 to be added to the data center 102 or simply enable a lower-cost operation of the data center 102. In addition, the lower speed fans would generate less noise.

In a second example, an unmanaged fluid delivery path allows for some mixing of the hot air 130b with the cold air 130a. In this example, the temperature rise may be reduced by increasing the fan speeds and/or reducing the temperature of the cold air 130a. Accordingly, if the hot air 130b is passed back through the electronic components 110 before reaching the fluid cooler 114, the electronic component 110 would not overheat, as will be appreciated by those skilled in the art.

The processor 128 in one example allows a user to control the air temperature rise and/or outlet temperatures of the cooling fluid. The user may specify an exhaust temperature, desired temperature rise, or other parameters. In another example, the processor 128 executes data center/building management software and determines the parameters based on the environmental characteristics, inlet temperatures, and outlet temperatures. The processor 128 allows the electronic components 110 to operate at higher temperatures in order to reduce energy used for cooling the electronic components 110.

As is known in the art, an increased operating temperature may reduce a mean time to failure of the electronic components 110. In one example, an operator of the data center 102 may plan for replacing the electronic components 110 with newer and faster electronic components after a pre-determined replacement time. The processor 128 in one example controls the cooling fluid such that the electronic components 110 operate at an elevated temperature. The processor 128 selects the elevated temperature such that the mean time to failure of the electronic components 110 is approximately equal to the pre-determined replacement time. The processor 128 may also use a buffer period in addition to the pre-determined replacement time to reduce the likelihood of the electronic components 110 failing while still in use, as will be appreciated by those skilled in the art.

Turning to FIG. 2, one implementation of a logic flow 200 is shown. The processor 128 in one example executes the logic flow 200 through employment of the recordable data storage medium 129. The processor 128 determines (STEP 202) a temperature rise for the electronic components 110 and/or the racks 108, for example, the desired temperature rise. The processor 128 then controls (STEP 204) the cooling fluid to maintain the desired temperature rise for the electronic components and/or the racks 108.

Numerous alternative implementations of the present invention exist. In one implementation, the cooling fluid may be water or a refrigeration coolant. In this implementation, the fans 120 and 126 may be replaced with variable output fluid pumps. In another implementation, several cooling techniques may be combined, such as using water and air cooling simultaneously within an electronic component 110 or using water cooling for a first rack and air cooling for a second rack, as will be appreciated by those skilled in the art.

The apparatus 100 in one example comprises a plurality of components such as one or more of electronic components, hardware components, and computer software components. A number of such components can be combined or divided in the apparatus 100. An example component of the apparatus 100 employs and/or comprises a set and/or series of computer instructions written in or implemented with any of a number of programming languages, as will be appreciated by those skilled in the art.

The apparatus 100 in one example employs one or more computer-readable signal-bearing media. The computer-readable signal-bearing media store software, firmware and/or assembly language for performing one or more portions of one or more implementations of the invention. Examples of a computer-readable signal-bearing medium for the apparatus 100 comprise the recordable data storage medium 129 of the processor 128. The computer-readable signal-bearing medium for the apparatus 100 in one example comprise one or more of a magnetic, electrical, optical, biological, and atomic data storage medium. For example, the computer-readable signal-bearing medium comprise floppy disks, magnetic tapes, CD-ROMs, DVD-ROMs, hard disk drives, and electronic memory.

The steps or operations described herein are just for example. There may be many variations to these steps or operations without departing from the spirit of the invention. For instance, the steps may be performed in a differing order, or steps may be added, deleted, or modified.

Although example implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. An apparatus, comprising:
a processor configured to control at least one characteristic of a cooling fluid supplied to an electronic component based on a temperature rise of the cooling fluid between an inlet and an outlet of the electronic component.

2. The apparatus of claim 1, wherein the processor is configured to control the at least one characteristic of the cooling fluid to maintain a desired temperature rise of the cooling fluid between the inlet and the outlet of the electronic component.

3. The apparatus of claim 2, wherein the processor is configured to determine the desired temperature rise based on at least one characteristic of an environment of the electronic component.

4. The apparatus of claim 3, wherein the at least one characteristic of the environment of the electronic component comprises at least one of:
a cooling capacity of a fluid cooler for the electronic component;
a cooling efficiency of the fluid cooler for the electronic component;
a fluid delivery path for the cooling fluid between the electronic component and the fluid cooler.

5. The apparatus of claim 3, wherein the processor is configured to determine the desired temperature rise to reduce energy used to supply the cooling fluid and maintain the electronic component within a desired operating temperature range.

6. The apparatus of claim 1, wherein the at least one characteristic of the cooling fluid comprises at least one of a velocity, a volume, a fluid delivery path, and a temperature of the cooling fluid.

7. The apparatus of claim 6, wherein the processor is coupled with at least one variable output fan, wherein the cooling fluid comprises air;
wherein the processor is configured to adjust the variable output fan to control the velocity and/or volume of the air supplied to the electronic component.

8. The apparatus of claim 6, wherein the processor is coupled with at least one variable output fluid pump, wherein the cooling fluid comprises liquid coolant;
wherein the processor is configured to adjust the variable output fluid pump to control the velocity and/or volume of the liquid coolant supplied to the electronic component.

9. The apparatus of claim 6, wherein the processor is coupled with at least one fluid cooler that supplies the cooling fluid to the electronic component;
wherein the processor is configured to adjust the at least one fluid cooler to control the temperature of the cooling fluid.

10. The apparatus of claim 1, wherein the processor is configured to control the at least one characteristic of the cooling fluid supplied to a plurality of electronic components within at least one rack of a data center based on a temperature rise of the cooling fluid between an inlet and outlet of the racks;
wherein the plurality of electronic components comprises the electronic component.

11. The apparatus of claim 10, wherein the fluid cooler controller determines the desired temperature rise based on at least one characteristic of the racks or the data center.

12. The apparatus of claim 11, wherein the at least one characteristic of the racks or the data center comprise at least one of:
a cooling capacity of a computer room air conditioner (CRAC) for the data center;
a cooling efficiency of the CRAC for the data center;
a fluid delivery path for the cooling fluid in the data center between the racks and the CRAC.

13. The apparatus of claim 12, wherein the fluid cooler controller determines a first desired temperature rise if the fluid delivery path comprises an indirect fluid delivery path;
wherein the fluid cooler controller determines a second desired temperature rise if the fluid delivery path comprises a direct fluid delivery path, wherein the first desired temperature rise is less than the second desired temperature rise.

14. A method, comprising the steps of:
determining a desired temperature rise for at least one electronic component in a rack of a data center to reduce energy used to supply cooling fluid to the at least one electronic component;
controlling at least one characteristic of the cooling fluid supplied to the at least one electronic component to maintain the desired temperature rise for the at least one electronic component.

15. The method of claim 14, wherein the step of determining the desired temperature rise for the at least one electronic component in the rack of the data center to reduce the energy used to supply the cooling fluid to the at least one electronic component comprises the step of:
determining the desired temperature rise based on at least one of a cooling capacity of a fluid cooler that supplies the cooling fluid, a cooling efficiency of the fluid cooler, and a fluid delivery path for the cooling fluid between the fluid cooler and the at least one electronic component.

16. The method of claim 14, wherein the step of controlling the at least one characteristic of the cooling fluid supplied to the at least one electronic component to maintain the desired temperature rise for the at least one electronic component comprises the step of:
controlling at least one of a velocity, a volume, a fluid delivery path, and a temperature of the cooling fluid.

17. The method of claim 16, wherein the step of controlling the at least one of the velocity, the volume, the fluid delivery path, and the temperature of the cooling fluid comprise at least one of the steps of:
reducing or increasing a rotational speed of an adjustable output fan;
closing or opening a vent;
increasing or reducing a temperature of the cooling fluid.

18. A computer readable storage medium on which is embedded at least one computer program comprising a set of instructions for:
determining a desired temperature rise for at least one electronic component in a rack of a data center to reduce energy used to supply cooling fluid to the at least one electronic component;
controlling at least one characteristic of the cooling fluid supplied to the at least one electronic component to maintain the desired temperature rise for the at least one electronic component.

19. The computer readable storage medium of claim 18, wherein the set of instructions for determining the desired temperature rise for the at least one electronic component in the rack of the data center to reduce the energy used to supply the cooling fluid to the at least one electronic component comprises a set of instructions for:
determining the desired temperature rise based on at least one of a cooling capacity of a fluid cooler that supplies the cooling fluid, a cooling efficiency of the fluid cooler, and a fluid delivery path for the cooling fluid between the fluid cooler and the at least one electronic component.

20. The computer readable storage medium of claim 18, wherein the set of instructions for controlling the at least one characteristic of the cooling fluid supplied to the at least one electronic component to maintain the desired temperature rise for the at least one electronic component comprises a set of instructions for:
controlling at least one of a velocity, a volume, a fluid delivery path, and a temperature of the cooling fluid.
